(19) United States
(12) Patent Application Publication
(10) Pub. No.: US 2015/0325762 A1
(43) Pub. Date: Nov. 12, 2015

(54) PACKAGE STRUCTURE AND MANUFACTURING METHOD THEREOF

(71) Applicant: Genesis Photonics Inc., Tainan City (TW)

(72) Inventors: Shou-Wen Hsu, Tainan City (TW); Yu-Feng Lin, Tainan City (TW); Cheng-Bin Liu, Changhua County (TW); Tai-Cheng Tsai, Kaohsiung City (TW); Chin-Hua Hung, Tainan City (TW)

(21) Appl. No.: 14/695,003

(22) Filed: Apr. 23, 2015

(30) Foreign Application Priority Data
May 6, 2014 (TW) 103116075

(51) Int. Cl. H01L 33/62; H01L 29/866; H01L 27/15

(52) U.S. Cl. CPC H01L 33/62; H01L 27/15; H01L 29/866; H01L 2933/0066

(57) ABSTRACT

A package structure and a manufacturing method thereof are disclosed. The package structure includes: a substrate; at least one light emitting diode disposed on the substrate by eutectic bonding; and at least one Zener diode disposed on the substrate by at least one silver glue. The method of manufacturing the package structure includes: providing a substrate; performing a eutectic bonding process to dispose at least one light emitting diode on the substrate; and performing a silver glue bonding process at room temperature to dispose at least one Zener diode on the substrate.

### CROSS-REFERENCE TO RELATED APPLICATION

This application claims the priority benefit of Taiwan application serial no. 103116075, filed on May 6, 2014. The entirety of the above-mentioned patent application is hereby incorporated by reference herein and made a part of this specification.

### BACKGROUND OF THE INVENTION

1. Field of the Invention

The invention relates to a package structure and a manufacturing method thereof, and particularly relates to a package structure of a light-emitting diode and a Zener diode and a manufacturing method thereof.

2. Description of Related Art

In the era of global energy shortage, high gasoline price, and high electricity price, and to cooperate with the policies of energy and carbon conservation, energy-saving lighting technologies have become the mainstream for further development. Many researches have been devoting efforts to develop products that may replace the conventional light sources and have a lower power consumption. Among these technologies, the lighting technology using light-emitting diodes (LED) is the most promising product in the replacing light sources.

LEDs have the advantages of small size, long lifetime, and low power consumption, etc., and are thus commonly used in indicators and display devices in electronic products. Thus, to increase the competitiveness on the market, manufacturers in the LED-related industries have been working hard to increase the yield rate and reduce the manufacturing cost, so as to become more advantageous.

To improve the efficiency of LED, a Zener diode with a voltage stabilizing function is commonly connected in parallel with an LED to prevent the LED from being damaged by an electrostatic discharge (ESD) or other high-voltage transient signals. The Zener diode operates to stably provide a reverse breakdown voltage when it is under a reverse voltage, and the Zener diode is an electronic device having a voltage stabilizing function. If a cross-LED reverse voltage is higher than the reverse breakdown voltage of the Zener diode, the electrical current may pass through the Zener diode to protect the LED.

Nowadays, eutectic bonding is commonly used to bond the LED and Zener diode on a substrate under a high temperature and a high pressure. However, if the Zener diode and LED are disposed on the substrate through eutectic bonding, one of the components (e.g., the Zener diode or LED) is inevitably heated repetitively. Thus, the high temperature in the manufacturing process may damage the Zener diode or LED. Thus, the function of LED or Zener diode may be influenced.

### SUMMARY OF THE INVENTION

Based on the above, the invention provides a package structure and a manufacturing method thereof to prevent a Zener diode or a light-emitting diode from being damaged due to a high temperature, thus influencing a function of the Zener diode or light-emitting diode.

Accordingly, the invention provides a package structure, at least including: a substrate, at least one light-emitting diode, disposed on the substrate through eutectic bonding; and, and at least one Zener diode, disposed on the substrate by using at least one silver glue.

According to an embodiment of the invention, a first pad and a second pad of the Zener diode are disposed on the substrate by using the silver glue and electrically connected to the substrate. According to an embodiment of the invention, materials of the first pad and the second pad of the Zener diode are selected from a group consisting of Sn, AuSn, AgSn, Au, and Al. Moreover, thicknesses of the first pad and the second pad of the Zener diode are respectively in a range from 80 micrometers to 170 micrometers.

According to an embodiment of the invention, at least one electrical wiring is further disposed on the substrate, and the light-emitting diode and the Zener diode are connected in parallel through the electrical wiring.

According to an embodiment of the invention, a thickness of the silver glue is in a range from 5 micrometers to 85 micrometers. According to an embodiment of the invention, a viscosity of the silver glue is in a range from 7000 centipoises to 17000 centipoises. According to an embodiment of the invention, the silver glue is formed of silver and a glue, and respective proportions in weight of silver and the glue with respect to the silver glue are in a range from 40% to 90%.

According to an embodiment of the invention, the Zener diode is disposed on the substrate by using the silver glue under room temperature.

Moreover, the invention further provides a manufacturing method of a package structure, at least including: providing a substrate; performing a eutectic bonding process to dispose at least one light-emitting diode on the substrate; and performing a silver glue bonding process under room temperature, so as to dispose at least one Zener diode on the substrate.

Based on the above, the package structure and the manufacturing method thereof according to the embodiments of the invention include one or more of the following characteristics:

In the package structure and the manufacturing method thereof according to the embodiments of the invention, the Zener diode is bonded to the substrate by using the silver glue. Thus, the Zener diode may be disposed on the substrate under room temperature, saving the cost and time.

In the package structure and the manufacturing method thereof according to the embodiments of the invention, repetitive heating and pressuring when adopting the conventional eutectic bonding process may be prevented. Thus, the Zener diode or the light-emitting diode may be prevented from being damaged.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view illustrating a package structure of the invention.

FIG. 2 is a cross-sectional schematic view illustrating that a Zener diode is disposed on a substrate by using a silver glue in a package structure of the invention.

FIG. 3 is a schematic view illustrating that a light-emitting diode and a Zener diode connected in parallel in a package structure of the invention.

FIG. 4 is a flowchart illustrating a manufacturing method of a package structure of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

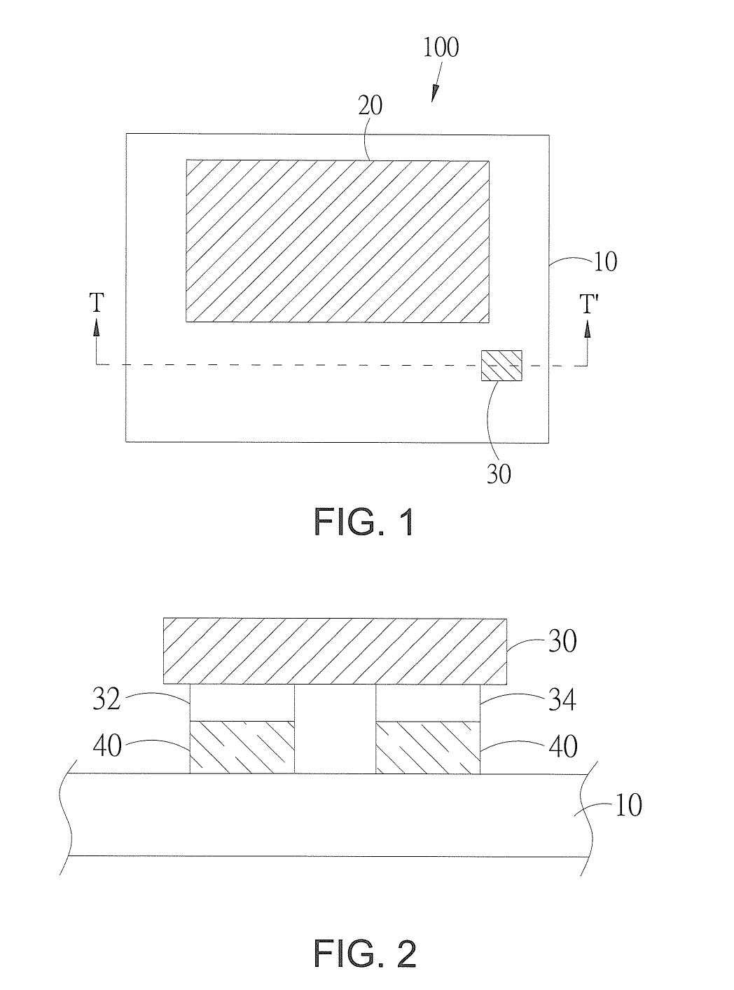

Referring to FIGS. 1 and 2 together, FIG. 1 is a top view illustrating a package structure of the invention, and FIG. 2 is a cross-sectional schematic view illustrating that a Zener diode is disposed on a substrate by using a silver glue in a package structure of the invention. As shown in FIG. 1, a package structure 100 of the invention at least includes a substrate 10, at least one light-emitting diode 20, and at least one Zener diode 30. The light-emitting diode 20 is disposed on the substrate 10 through eutectic bonding. Eutectic bonding is already well known by people having ordinary skills in the art. Thus, details regarding eutectic bonding will not be repeated in the following.

Referring to FIG. 2, FIG. 2 is a cross-sectional schematic view illustrating the Zener diode 30 is disposed on the substrate 10 taken along a cross-sectional line T-T′ shown in FIG. 1. As shown in FIG. 2, a first pad 32 and a second pad 34 of the Zener diode 30 may be disposed on the substrate 10 by using a silver glue 40 and electrically connected with the substrate 10, for example. In addition, the first pad 32 of the Zener diode 30 is an N-type pad, for example, and the second pad 34 is a P-type pad, for example. However, the invention is not limited thereto. Materials of the first pad 32 and the second pad 34 may be selected from a group consisting of Sn, AuSn, AgSn, Au, and Al, for example. In addition, the materials of the first pad 32 and the second pad 34 of the Zener diode 30 are preferably Au. Using Au as the materials of the first pad 32 and the second pad 34 of the Zener diode 30 may result in a more preferable bonding effect with the silver glue 40.

Moreover, thicknesses of the first pad 32 and the second pad 34 of the Zener diode 30 may be respectively in a range from 80 micrometers to 170 micrometers, for example. However, the invention is not limited thereto. A thickness of the silver glue 40 may be in a range from 5 micrometers to 85 micrometers. However, the invention is not limited thereto. Since in the invention, the Zener diode 30 is disposed on the substrate 10 by using the silver glue 40, the thicknesses of the first pad 32 and the second pad 34 of the Zener diode 30 may be thinner than the thickness of a pad used for the conventional eutectic bonding. Moreover, the thickness of the silver glue 40 is thinner than a thickness of the silver glue conventionally used to bond electronic devices. Thus, a thermal resistance of the silver glue 40 is reduced, and a heat dissipation performance is consequently more preferable.

A viscosity of the silver glue 40 may be in a range from 7000 centipoises to 17000 centipoises, for example. Moreover, the silver glue 40 may be formed of silver and a glue, and respective proportions in weight of silver and the glue with respect the silver glue may be in a range from 40% to 90%, for example. In other words, the proportion in weight of silver or the glue with respect to the silver glue 40 may be in the range from 40% to 90%, for example. Moreover, a material of the glue may be epoxy resin or silica gel, for example. However, the invention is not limited thereto. The viscosity, forming components, and weight proportion concerning the silver glue 40 are only described herein as examples. Any viscosity, forming components, and weight proportion of the silver glue 40 that allows the Zener diode 30 to be adhered on the substrate 10 fall within the scope claimed in the invention.

Since the silver glue 40, instead of eutectic bonding, is used in the invention to dispose the Zener diode 30 on the substrate 10, the Zener diode 30 may be disposed on the substrate 10 by using the silver glue 40 under room temperature. In other words, according to the invention, it is not required a high temperature to dispose the Zener diode 30. Thus, the Zener diode 30 may not be damaged by a high temperature manufacturing process. Also, by using the silver glue 40 to directly electrically connect the Zener diode 30 to the substrate 10, a wiring bonding process is not required. Thus, manufacturing processes and cost may be reduced.

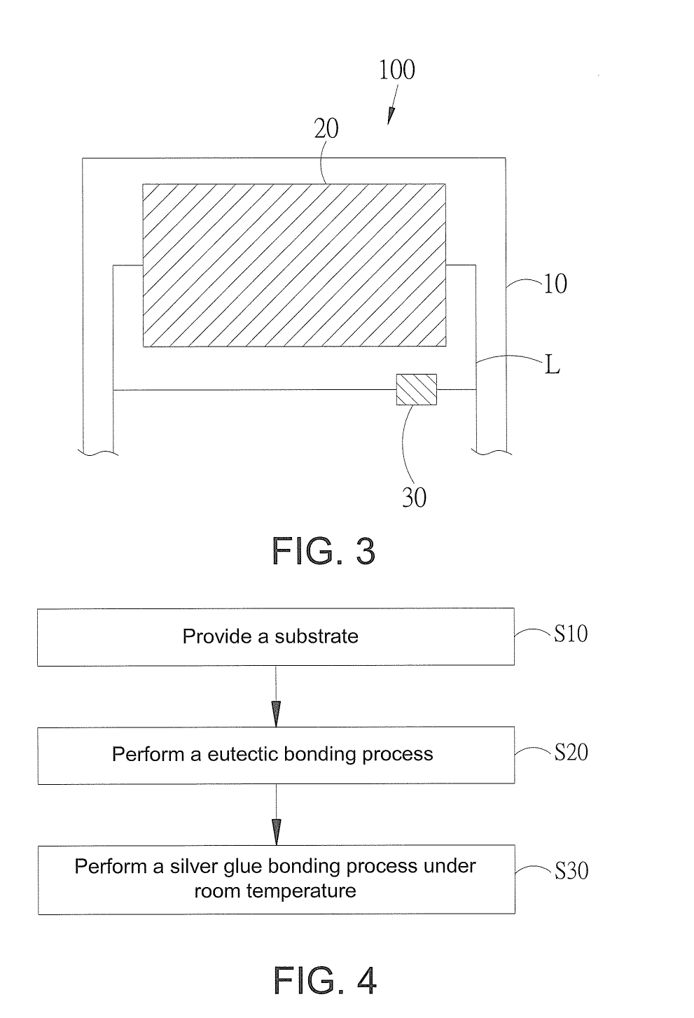

FIG. 3 is a schematic view illustrating that a light-emitting diode and a Zener diode connected in parallel in a package structure of the invention. As shown in FIG. 3, at least one electrical wiring L is disposed on the substrate 10, such that the light-emitting diode 20 and the Zener diode 30 are connected in parallel through the electrical wiring L. Thus, since the Zener diode 30 having the first pad 32 and the second pad 34 at the same side is used in the invention, the first pad 32 and the second pad 34 are bonded on the substrate 10 by using the silver glue 40 (see FIG. 2), and a flip-chip light-emitting diode, for example, may be chosen as the light-emitting diode 20, the light-emitting diode 20 and the Zener diode 30 may be connected in parallel through the electrical wiring L disposed on the substrate 10 in the package structure of the invention, and it is not necessary to perform an additional wiring process or design an additional electrical wiring. Thus, the manufacturing processes and cost may be reduced, and the package structure may be further miniaturized.

The invention also discloses a manufacturing method of a package structure. Referring to FIG. 4, FIG. 4 is a flowchart illustrating a manufacturing method of a package structure of the invention. Referring to FIGS. 1, 2, and 4 of the invention, a manufacturing method of the package structure 100 of the invention at least includes Steps S10, S20, and S30. At Step S10, the substrate 10 is provided. At Step S20, a eutectic bonding process is performed to dispose the at least one light-emitting diode 20 on the substrate 10. At Step S30, a silver glue bonding process is performed under room temperature to dispose the at least one Zener diode 30 on the substrate 10.

In the manufacturing method of the package structure of the invention, the light-emitting diode 20 may be disposed on the substrate 10 through eutectic bonding, and then the Zener diode 30 is disposed on the substrate 10 by using the silver glue 40 under room temperature. Thus, when performing the process of disposing the Zener diode 30 on the substrate 10 by using the silver glue 40, the light-emitting diode 20 is not repetitively heated because the process is performed under room temperature. Consequently, the function of the light-emitting diode 20 is not influenced for being heated. Alternatively, the Zener diode 30 may be disposed on the substrate 10 by using the silver glue 40 under room temperature, and then the light-emitting diode 20 is disposed on the substrate 10 through eutectic bonding. Thus, the Zener diode 30 is not repetitively heated, and the function of the Zener diode 30 is not influenced for being heated. The influence of repetitively heating a component on the function of the package structure may be prevented regardless of which manufacturing method is adopted.

In view of the foregoing, the Zener diode is bonded to the substrate by using the silver glue in the invention. Thus, the Zener diode is bonded under room temperature, and damages to the light-emitting diode is prevented. Also, the Zener diode and the light-emitting diode are bonded on the substrate by using a simplified manufacturing process, making the manufacturing process more practical and convenient.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package structure, at least comprising:
a substrate;
at least one light-emitting diode, disposed on the substrate through eutectic bonding; and
at least one Zener diode, disposed on the substrate by using at least one silver glue.

2. The package structure as claimed in claim 1, wherein a first pad and a second pad of the Zener diode are disposed on the substrate by using the silver glue and electrically connected to the substrate.

3. The package structure as claimed in claim 2, wherein materials of the first pad and the second pad of the Zener diode are selected from a group consisting of Sn, AuSn, AgSn, Au, and Al.

4. The package structure as claimed in claim 2, wherein thicknesses of the first pad and the second pad of the Zener diode are respectively in a range from 80 micrometers to 170 micrometers.

5. The package structure as claimed in claim 2, wherein the first pad of the Zener diode is an N-type pad, and the second pad of the Zener diode is a P-type pad.

6. The package structure as claimed in claim 1, wherein at least one electrical wiring is further disposed on the substrate, and the light-emitting diode and the Zener diode are connected in parallel through the electrical wiring.

7. The package structure as claimed in claim 1, wherein a thickness of the silver glue is in a range from 5 micrometers to 85 micrometers.

8. The package structure as claimed in claim 1, wherein a viscosity of the silver glue is in a range from 7000 centipoises to 17000 centipoises.

9. The package structure as claimed in claim 1, wherein the silver glue is formed of silver and a glue, and respective proportions in weight of silver and the glue with respect to the silver glue are in a range from 40% to 90%.

10. The package structure as claimed in claim 1, wherein the Zener diode is disposed on the substrate by using the silver glue under room temperature.

11. A manufacturing method of a package structure, at least comprising:
providing a substrate;
performing an eutectic bonding process to dispose at least one light-emitting diode on the substrate; and
performing a silver glue bonding process under room temperature, so as to dispose at least one Zener diode on the substrate.

12. The manufacturing method of the package structure as claimed in claim 11, wherein a first pad and a second pad of the Zener diode are disposed on the substrate by using the silver glue and electrically connected to the substrate.

13. The manufacturing method of the package structure as claimed in claim 12, wherein materials of the first pad and the second pad of the Zener diode are selected from a group consisting of Sn, AuSn, AgSn, Au, and Al.

14. The manufacturing method of the package structure as claimed in claim 12, wherein thicknesses of the first pad and the second pad of the Zener diode are respectively in a range from 80 micrometers to 170 micrometers.

15. The manufacturing method of the package structure as claimed in claim 12, wherein the first pad of the Zener diode is an N-type pad, and the second pad of the Zener diode is a P-type pad.

16. The manufacturing method of the package structure as claimed in claim 11, wherein at least one electrical wiring is further disposed on the substrate, and the light-emitting diode and the Zener diode are connected in parallel through the electrical wiring.

17. The manufacturing method of the package structure as claimed in claim 11, wherein a thickness of the silver glue is in a range from 5 micrometers to 85 micrometers.

18. The manufacturing method of the package structure as claimed in claim 11, wherein a viscosity of the silver glue is in a range from 7000 centipoises to 17000 centipoises.

19. The manufacturing method of the package structure as claimed in claim 11, wherein the silver glue is formed of silver and a glue, and respective proportions in weight of silver and the glue with respect to the silver glue are in a range from 40% to 90%.

20. The manufacturing method of the package structure as claimed in claim 11, wherein the Zener diode is disposed on the substrate by using the silver glue under room temperature.
